(19) United States
(12) Patent Application Publication
(10) Pub. No.: US 2008/0068914 A1
(43) Pub. Date: Mar. 20, 2008

(54) OUTPUT DRIVING CIRCUIT AND SEMICONDUCTOR MEMORY DEVICE HAVING THE SAME

(76) Inventor: You-Chul Jeong, Suwon-si (KR)

Correspondence Address: F. CHAU & ASSOCIATES, LLC, 130 WOODBURY ROAD, WOODBURY, NY, 11797, US

(21) Appl. No.: 11/780,229

(22) Filed: Jul. 19, 2007

(30) Foreign Application Priority Data
Sep. 15, 2006 (KR) 2006-0089647

(51) Int. Cl. G11C 5/14

(52) U.S. Cl. 365/226

(57) ABSTRACT

An output driver, memory device and corresponding method are provided, the output driver having two transistors with their drains commonly connected and each of two sources of the two transistors connected to a separate supply node of a same polarity power supply, and a decoupling capacitor connected to each source; and the memory device having an output driver with a plurality of connected drivers, each driver having a transistor of a first type connected to a transistor of a second type to provide an output drive signal therebetween, and at least one decoupling capacitor, the output driver circuit having a plurality of first voltage supply nodes adapted to connect to a first voltage supply and a plurality of second voltage supply nodes adapted to connect to a second voltage supply, and at each odd driver, the transistor of the first type is made up of two transistors commonly connected at the connection with the transistor of the second type, but separately connected to different first voltage supply nodes; and the method including switching a transistor of a first type connected to a transistor of a second type to provide an output drive signal therebetween.

### CROSS-REFERENCE TO RELATED APPLICATION

This application claims foreign priority under 35 U.S.C. § 119 to Korean Patent Application No. P2006-0089647 (Atty. Dkt. ID2006050411) filed on Sep. 15, 2006, in the Korean Intellectual Property Office, the disclosure of which is incorporated by reference herein in its entirety.

### BACKGROUND OF THE INVENTION

The present disclosure generally relates to semiconductor memory devices, and more particularly relates to semiconductor memory devices with output driver circuits. In conventional memory devices, as the capacity of a memory device is increased, the amount of data to be input and output is also increased. Thus, more input and/or output pins may be needed. In addition, as modern systems require ever-faster memory devices, the switching noise increases over slower devices.

As shown in FIG. 1 an output driver circuit of a semiconductor memory device is presented for background purposes and indicated generally by the reference numeral 100. The output driver circuit 100 includes a DQ PIN terminal connected to a DATA signal line, a PMOS pull-up transistor MP1 connected between the DATA signal line and a relatively high voltage level VDDQ, and an NMOS pull-down transistor MN1 connected between the DATA signal line and a relatively low voltage level VSSQ. A gate terminal of the pull-up transistor MP1 is connected to a DATA_UP signal line, and a gate terminal of the pull-down transistor MN1 is connected to a DATA_DN signal line.

In operation of the driver circuit 100, the NMOS transistor and the PMOS transistor switch the signal DQ from logic “low” to logic “high” or from logic “high” to logic “low” in response to the input signals DATA_UP or DATA_DN. Unfortunately, during a switching operation, switching noise is presented on the output signal path. Further, since the output driver is operated at high-speed for a high-speed memory device, the switching noise increases on the VDDQ/VSSQ lines in proportion to the speed. In addition, since the VDDQ/VSSQ lines supply electric power to output driver, the output signal is distorted and exhibits changes such as jitter, skew and/or slew rate as the switching noise increases.

### SUMMARY OF THE INVENTION

These and other issues are addressed by an output driving circuit and semiconductor memory device having the same. Exemplary embodiments are provided.

An exemplary output driver includes two transistors having their drains commonly connected and each of two sources of the two transistors connected to a separate power supply node, and a decoupling capacitor connected to each source.

A further exemplary output driver also includes a third transistor connected to the drains of the two transistors and connected to a third power supply node. Yet another exemplary output driver includes separate power supply nodes connected to the sources of the two transistors; adapted to be connected to a common power supply. Still another exemplary output driver includes separate power supply nodes connected to the sources of the two transistors adapted to be connected to a common power supply, where the third power supply node is adapted to be connected to a second power supply. In a further exemplary output driver, the two transistors are PMOS transistors. In yet another exemplary output driver, the third transistor is an NMOS transistor. In still another exemplary output driver the common power supply provides a more positive voltage than the second power supply. In a further exemplary output driver the two transistors are NMOS transistors.

Another exemplary output driver circuit includes a plurality of connected drivers, each driver having a transistor of a first type connected to a transistor of a second type to provide an output drive signal therebetween, and at least one decoupling capacitor, the output driver circuit comprising a plurality of first voltage supply nodes adapted to connect to a first voltage supply and a plurality of second voltage supply nodes adapted to connect to a second voltage supply, and at each odd driver, the transistor of the first type is made up of two transistors commonly connected at the connection with the transistor of the second type, but separately connected to different first voltage supply nodes.

In a further exemplary output driver, the transistor of the second type at each even driver is made up of two transistors commonly connected at the connection with the transistor of the first type, but separately connected to different second voltage supply nodes. In yet another exemplary output driver the transistors of the first type are PMOS and the transistors of the second type are NMOS. Still another exemplary output driver includes in each driver two decoupling capacitors, one downstream and one upstream. In a further exemplary output driver, each of the two transistors at each odd driver is about one half of the size of the transistor of the first type. In yet another exemplary output driver, each of the two transistors at each even driver is about one half of the size of the transistor of the second type. In still another exemplary output driver, one of the two transistors that make up the transistor of the first type is connected to the first voltage supply node connected downstream of the odd driver and the other of the two transistors is connected to the first voltage supply node connected upstream of the odd driver. In a further exemplary output driver, one of the two transistors that make up the transistor of the second type is connected to the second voltage supply node connected downstream of the even driver and the other of the two transistors is connected to the second voltage supply node connected upstream of the even driver. In yet another exemplary output driver, the aggregate current drive of the two transistors is about the same as the current drive of the transistor of the first type. Still another exemplary output driver includes a first voltage supply node connected downstream of each odd driver and a second voltage supply node connected downstream of each even driver.

An exemplary method of driving an output of a semiconductor memory device includes switching a transistor of a first type connected to a transistor of a second type to provide an output drive signal therebetween, decoupling the output drive signal with at least one capacitor connected substantially in parallel with the first and second transistors, and reducing the switching noise by providing a plurality of first voltage supply nodes adapted to connect to a first voltage supply and a plurality of second voltage supply nodes adapted to connect to a second voltage supply and providing at a first plurality of the transistors of the first or second type another transistor of the first or second type, respectively, commonly connected at the connection with the transistor of the second or first type, respectively, but separately connected to different first or second voltage supply nodes, respectively.

A further exemplary method also includes further reducing the switching noise by providing at a second plurality of the transistors of the second or first type another transistor of the second or first type, respectively commonly connected at the connection with the transistor of the first or second type, respectively, but separately connected to different second or first voltage supply nodes, respectively.

The present disclosure will be further understood from the following description of exemplary embodiments, which is to be read in connection with the accompanying drawings.

### BRIEF DESCRIPTION OF THE DRAWINGS

The present disclosure provides output driving circuit and semiconductor memory device having the same in accordance with the following exemplary figures, in which;

FIG. 1 shows a schematic circuit diagram for an output driver circuit of a semiconductor memory device, which is provided as background material;

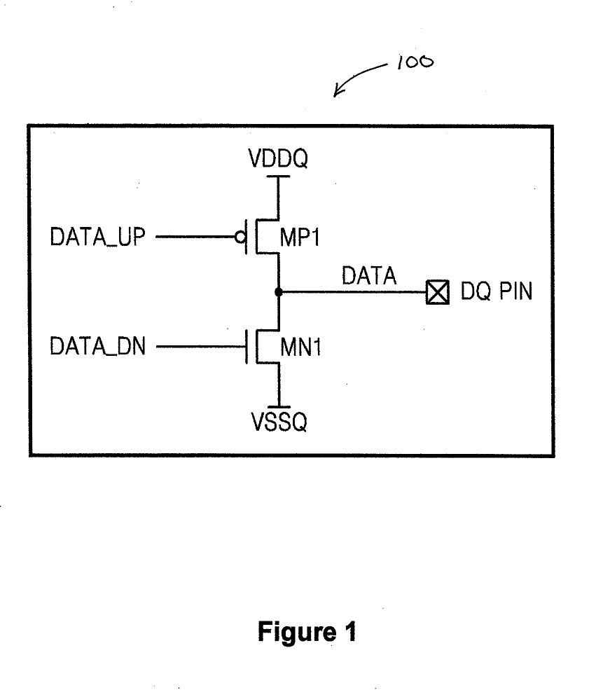

FIG. 2 shows a schematic circuit diagram of an output driver circuit for reducing switching noise in memory device;

FIG. 3 shows a schematic circuit diagram of an output driver circuit for reducing noise coupling in a memory device;

FIG. 4 shows a schematic circuit diagram of an output driver circuit for further reducing switching noise and noise coupling in accordance with a preferred embodiment of the present disclosure;

FIG. 5 shows a schematic circuit diagram of an output driver circuit with noise coupling in accordance with an exemplary embodiment of the present disclosure;

FIG. 6 shows a schematic block diagram of an output driver circuit without substantial line resistance in accordance with an exemplary embodiment of the present disclosure;

FIG. 7 shows a table of simulation results in accordance with an exemplary embodiment of the present disclosure; and

FIG. 8 shows a schematic flow diagram for a method of driving an output circuit in accordance with an exemplary embodiment of the present disclosure.

### DETAILED DESCRIPTION OF PREFERRED EMBODIMENTS

The present disclosure provides improved output driver circuits usable in semiconductor memory devices. The improved output driver circuits are capable of reducing switching noise and noise coupling, as well as stabilizing output data.

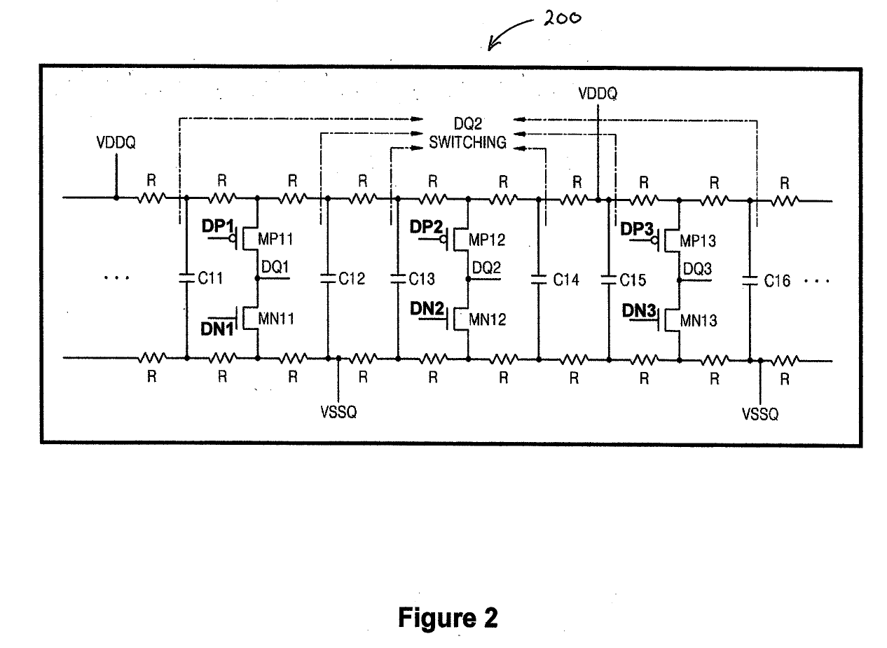

Turning to FIG. 2, a first output driver circuit for reducing switching noise in memory device is indicated generally by the reference numeral 200. The output driver circuit 200 includes a relatively higher voltage line VDDQ having a plurality of equivalent resistors R coupled in series, and a relatively lower voltage line VSSQ having a plurality of equivalent resistors R coupled in series.

A capacitor C11 is connected between a first resistor R on the VDDQ line and a first resistor R on the VSSQ line. A first driver transistor pair, including a pull-up PMOS transistor MP11 connected to a pull-down NMOS transistor MN11, is connected between a second resistor R on the VDDQ line and a second resistor R on the VSSQ line.

The source terminal of the PMOS transistor MP11 is connected to VDDQ, the drain terminal of MP11 is connected to the drain terminal of the NMOS transistor MN11 and the source terminal of MN11 is connected to VSSQ. A signal DP1 is applied to the gate of the PMOS transistor MP11, a signal DN1 is applied to the gate of the NMOS transistor MN11 and an output signal DQ1 is produced where the drain of MP11 meets the drain of MN11.

A capacitor C12 is connected between a third resistor R on the VDDQ line and a third resistor R on the VSSQ line. Another capacitor C13 is connected between a fourth resistor R on the VDDQ line and a fourth resistor R on the VSSQ line. A second driver transistor pair, including a pull-up PMOS transistor MP12 connected to a pull-down NMOS transistor MN12 is connected between a fifth resistor R on the VDDQ line and a fifth resistor R on the VSSQ line. The second driver transistor pair has the same structure as the first driver transistor pair described above, but the PMOS gate receives a signal DP2, the NMOS gate receives a signal DN2, and the output is designated DQ2.

A capacitor C14 is connected between a sixth resistor R on the VDDQ line and a sixth resistor R on the VSSQ line. Another capacitor C15 is connected between a seventh resistor R on the VDDQ line and a seventh resistor R on the VSSQ line. A third driver transistor pair, including a pull-up PMOS transistor MP13 connected to a pull-down NMOS transistor MN13, is connected between an eighth resistor R on the VDDQ line and an eighth resistor R on the VSSQ line. The third driver transistor pair has the same structure as the first and second driver transistor pairs described above, but the PMOS gate receives a signal DP3, the NMOS gate receives a signal DN3, and the output is designated DQ3. A capacitor C16 is connected between a ninth resistor R on the VDDQ line and a ninth resistor R on the VSSQ line.

Here, the signals DP1, DP2 and DP3, or DPn in general, as well as the signals DN1, DN2 and DN3, or DNn in general, are internal input signals applied to produce the output signals DQ1, DQ2 and DQ3, or DQn in general. The output driver is connected to the VDDQ/VSSQ lines. The resistors R may be the resistance for portions of the VDDQ/VSSQ metal lines rather than discrete components.

The decoupling capacitors C11 through C16 may reduce switching noise when connected between the VDDQ line and the VSSQ line. A larger capacity capacitor is more effective to reduce switching noise than a smaller capacitor, but there is a limitation on capacitor size due to internal space limitations of semiconductor memory devices. At least one decoupling capacitor can be adjacent or assigned to each output driver. For example, decoupling capacitors C11 and C12 are assigned to the first output driver with transistors MP11 and MN11, and decoupling capacitors C13 and 014 are assigned to the second driver with transistors MP12 and MN12.

In operation, the switching noise is reduced further by sharing the decoupling capacitors assigned to other output drivers. For example, the output driver of MP12/MN12 for providing DQ2 is used to supply the necessary current from a decoupling capacitor assigned to another output driver. Since there is a current loss generated by the resistance of the VDDQ/VSSQ lines, a decoupling capacitor far from the operating output driver is less effective than a closer one. In addition, in a case where most or all output drivers are operating, noise at adjacent output drivers affects neighbors. In other words, noise coupling can be present in this example.

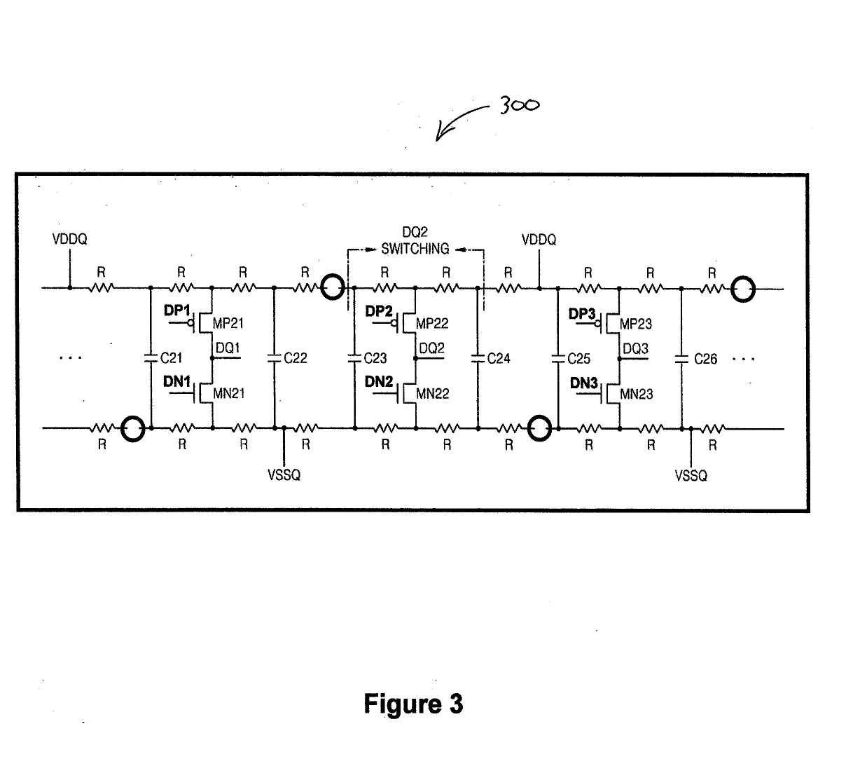

Turning now to FIG. 3, an output driver circuit for reducing noise coupling in a memory device is indicated generally by the reference numeral 300. The output driver circuit 300 is somewhat similar to the output driver circuit 200 of FIG. 2.

A capacitor C21 is connected between a first resistor R on the VDDQ line and a first resistor R on the VSSQ line, but the VSSQ line is split at the first resistor. A first driver transistor pair, including a pull-up PMOS transistor MP21 connected to a pull-down NMOS transistor MN21 is connected between a second resistor R on the VDDQ line and a second resistor R on the VSSQ line.

The source terminal of the PMOS transistor MP21 is connected to VDDQ, the drain terminal of MP21 is connected to the drain terminal of the NMOS transistor MN21, and the source terminal of MN21 is connected to VSSQ. A signal DP1 is applied to the gate of the PMOS transistor MP21, a signal DN1 is applied to the gate of the NMOS transistor MN21 and an output signal DQ1 is produced where the drain of MP21 meets the drain of MN21.

A capacitor C22 is connected between a third resistor R on the VDDQ line and a third resistor R on the VSSQ line. Another capacitor C23 is connected between a fourth resistor R on the VDDQ line and a fourth resistor R on the VSSQ line, but the VDDQ line is split at the fourth resistor. A second driver transistor pair, including a pull-up PMOS transistor MP22 connected to a pull-down NMOS transistor MN22, is connected between a fifth resistor R on the VDDQ line and a fifth resistor R on the VSSQ line. The second driver transistor pair has the same structure as the first driver transistor pair described above, but the PMOS gate receives a signal DP2, the NMOS gate receives a signal DN2, and the output is designated DQ2.

A capacitor C24 is connected between a sixth resistor H on the VDDQ line and a sixth resistor R on the VSSQ line. Another capacitor C25 is connected between a seventh resistor R on the VDDQ line and a seventh resistor R on the VSSQ line, but the VSSQ line is split at the seventh resistor. A third driver transistor pair, including a pull-up PMOS transistor MP23 connected to a pull-down NMOS transistor MN23, is connected between an eighth resistor R on the VDDQ line and an eighth resistor R on the VSSQ line. The third driver transistor pair has the same structure as the first and second driver transistor pairs described above, but the PMOS gate receives a signal DP3, the NMOS gate receives a signal DN3, and the output is designated DQ3. A capacitor C26 is connected between a ninth resistor R on the VDDQ line and a ninth resistor R on the VSSQ line.

Here, one of the VDDQ or VSSQ lines splits based on each output driver. For example, the VDDQ line is split between the output driver for DQ1 (transistors MP21 and MN21) and the output driver for DQ2 (transistors MP22 and MN22). The VSSQ line is split between the output driver for DQ2 (transistors MP22 and MN22) and the output driver for DQ3 (transistors MP23 and MN23). In operation, the output driver circuit of this embodiment effectively reduces the undesirable effects of noise coupling, but the number of shared decoupling capacitors is decreased compared with the output driver circuit 200 of FIG. 2.

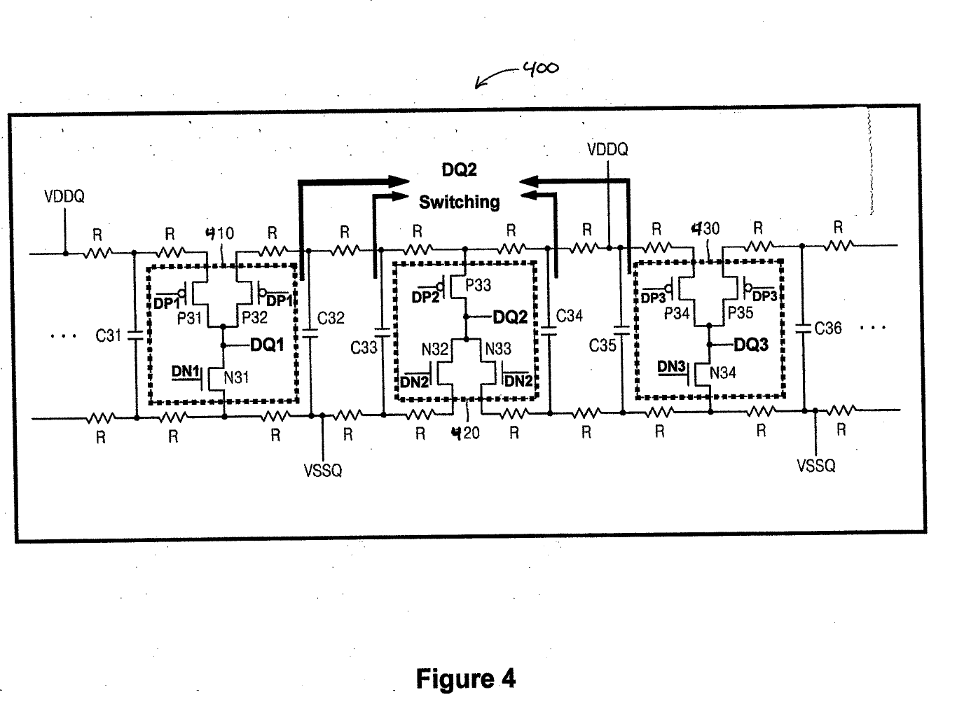

As shown in FIG. 4, a particularly preferred output driver circuit of the present disclosure is indicated generally by the reference numeral 400. The output driver circuit 400 includes a relatively higher voltage line VDDQ having a plurality of equivalent resistors R coupled substantially in series, and a relatively lower voltage line VSSQ having a plurality of equivalent resistors R coupled in series. A capacitor C31 is connected between a tail of a first resistor R on the VDDQ line and a tail of a first resistor R on the VSSQ line.

A first driver transistor trio 410 includes two pull-up transistors P31 and P32 connected to a pull-down transistor N31, and is connected between a tail of a second resistor R on the VDDQ line and a tail of a second resistor R on the VSSQ line. The source terminal of the transistor P31 is connected to the tail of the second resistor R on the VDDQ line, the drain terminal of P31 is connected to the drain terminal of the transistor N31 and to the drain terminal of the transistor P32. The source terminal of P32 makes the only connection to the head of the third resistor R on the VDDQ line, and the source terminal of N31 is connected to the tail of the second resistor and head of the third resistor on the VSSQ line. A signal DP1 is applied to the gates of the transistors P31 and P32, a signal DN1 is applied to the gate of the transistor N31, and an output signal DQ1 is produced where the drains of P31, N31 and P32 all meet. A capacitor C32 is connected between a tail of a third resistor R on the VDDQ line and a tail of a third resistor R on the VSSQ line. Another capacitor C33 is connected between a tail of a fourth resistor R on the VDDQ line and a tail of a fourth resistor R on the VSSQ line.

A second driver transistor trio 420 includes a pull-up transistor P33 connected to two pull-down transistors N32 and N33, and is connected between a tail of a fifth resistor R on the VDDQ line and a tail of a fifth resistor R on the VSSQ line. The second driver transistor trio has the opposite structure as the first driver transistor trio described above. That is, the source terminal of the transistor P33 is connected to the tail of the fifth resistor R on the VDDQ line, the drain terminal of P33 is connected to the drain terminal of the transistors N32 and N33. The source terminal of N32 makes the only connection to the tail of the fifth resistor on the VSSQ line, and the source terminal of N33 makes the only connection to the head of the sixth resistor on the VSSQ line. In addition, the gate of P33 receives a signal DP2, the gates of transistors N32 and N33 receive a signal DN2, and the output is designated DQ2. A capacitor C34 is connected between a tail of a sixth resistor R on the VDDQ line and a tail of a sixth resistor R on the VSSQ line. Another capacitor C35 is connected between a tail of a seventh resistor R on the VDDQ line and a tail of a seventh resistor R on the VSSQ line.

A third driver transistor trio 430 includes two pull-up transistors P34 and P35 connected to a pull-down transistor N34, and is connected between a tail of an eighth resistor R on the VDDQ line and a tail of an eighth resistor R on the VSSQ line. The third driver transistor trio 430 has the same structure as the first driver transistor trio 410 described above, but the gates of P34 and P35 receive a signal DP3, the gate of N34 receives a signal DN3, and the output is designated DQ3. A capacitor C36 is connected between a tail of a ninth resistor R on the VDDQ line and a tail of a ninth resistor R on the VSSQ line.

This embodiment has reduced switching noise compared with the driving circuits 200 and 300 of FIGS. 2 and 3, respectively. For example, consider when the DQ2 driver of the driver circuit 400 outputs data. The transistors N32 and N33, which are arranged in parallel each only carry half the current of the transistor P33, and may thus be only half the size of P33 or of transistors in previous driver circuits. Likewise, the transistors P31 and P32 which are also arranged in parallel, are only half the size of N31 or transistors in previous driver circuits. When the output driver 420 turns to a high level, the transistor P33 is turned on, and transistors N32 and N33 are turned off, all in response to the input signals DP2 and DN2.

Here, the decoupling capacitors C32 and C35 are shared when the DQ2 driver operates. This output driver circuit can therefore reduce switching noise because it supplies enough current using shared decoupling capacitors. It reduces switching noise even more than the circuit 300 of FIG. 3, which splits the VDDQ/VSSQ lines. The number of shared decoupling capacitors is less than circuit 200 of FIG. 2, which does not split the VDDQ/VSSQ lines. The current supplied to the decoupling capacitors far from the operating output driver is small because the VDDQ/VSSQ lines do have resistance. Thus, the shared current capacity is almost the same as for the circuit 200 of FIG. 2, and quite sufficient.

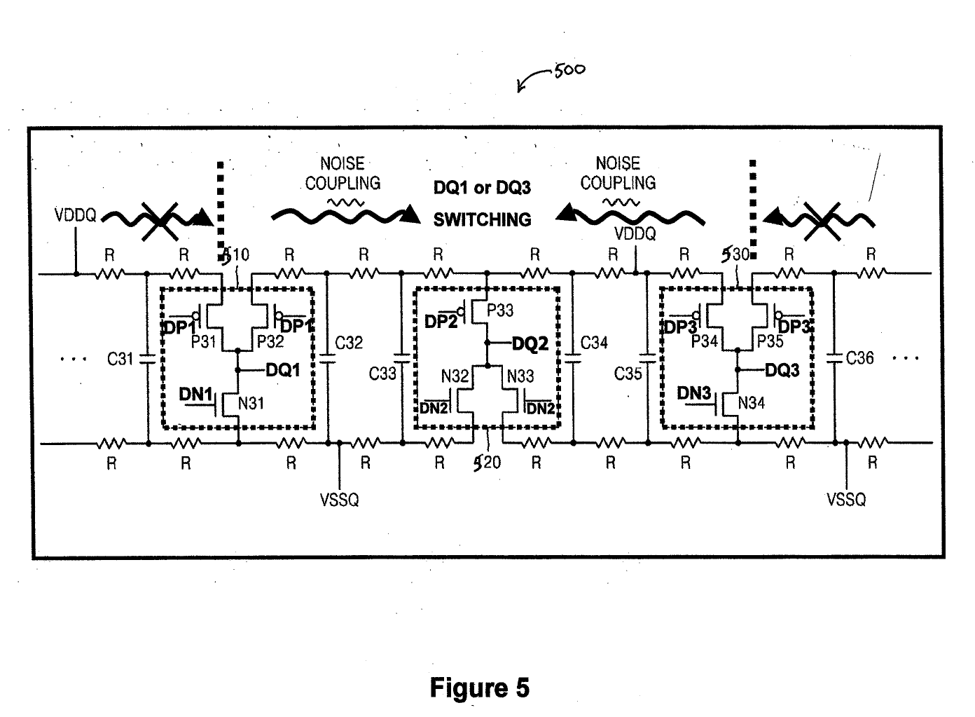

Turning to FIG. 5, an output driver circuit is shown with noise coupling and indicated generally by the reference numeral 500. The circuit 500 is substantially similar to the circuit 400 of FIG. 4, so duplicate description will be omitted. For noise coupling, if the noise occurs at output driver DQ1 or DQ3, it tries to influence the output of driver DQ2. This is the definition of noise coupling. Preferred embodiments of the present disclosure, including the driver circuits 400 and 500 of FIGS. 4 and 5, respectively, substantially eliminate the undesirable effects of noise coupling from the other output drivers, except for noise occurring immediately adjacent to the output driver. Thus, these driver circuits can substantially reduce the undesirable effects of noise coupling.

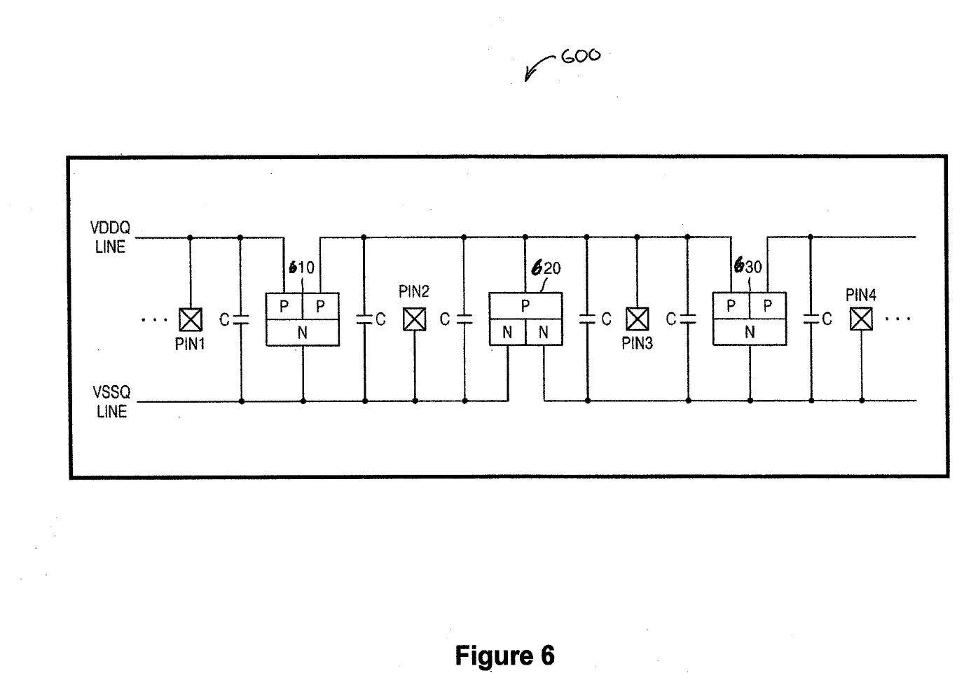

Turning now to FIG. 6, an output driver circuit is shown without substantial line resistance in block diagram form, and indicated generally by the reference numeral 600. Here, a first output driver 610 is supplied VDDQ by Pin1 and supplied VSSQ by Pin2, A second output driver 620 shares Pin2 with the first output driver, and is supplied VDDQ by Pin3. A third output driver 630 shares Pin3 with the second output driver, and is supplied VSSQ by Pin4. The first and third or odd-numbered output drivers 610 and 630 have the same structure, while the second or even-numbered output drivers have the opposite structure.

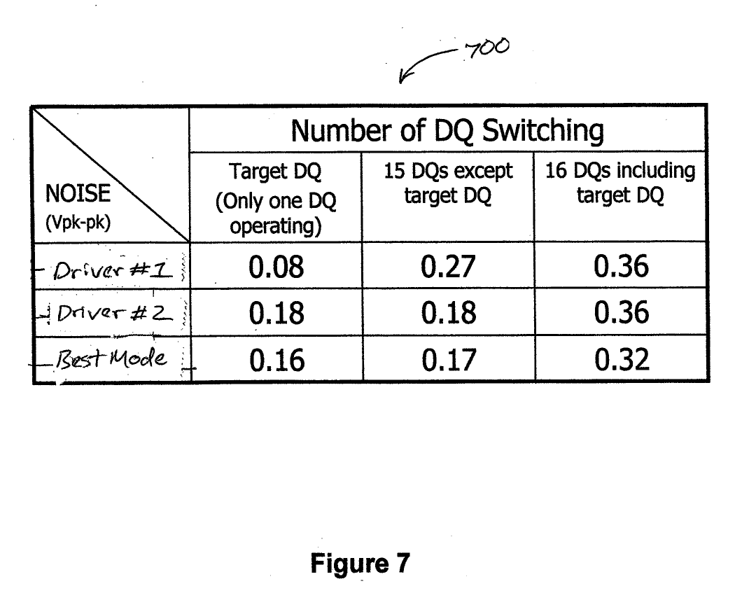

As shown in FIG. 7, exemplary simulation results for embodiments of the present disclosure are indicated generally by the reference numeral 700. The simulation conditions include a temperature of 25° C., a voltage of 1.8V, and a typical transistor type as known in the art. It shall be understood that alternate embodiments of the present disclosure are not limited by transistor type.

In the results, Driver#1 is an output driver circuit with non-splitting VDDQ/VSSQ lines, such as the driver circuit 200 of FIG. 2. Driver#2 is an output driver circuit with splitting VDDQ/VSSQ lines, such as the driver circuit 300 of FIG. 3. BestMode is an output driver circuit with controlled VDDQ/VSSQ lines, such as the driver circuit 400 of FIG. 4. When only one output driver operates, Driver#1 has the least noise because the effect of noise coupling is ignored. On the other hand, when a plurality of output drivers operate, BestMode has the smallest noise because of reduced noise coupling and reduced internal noise from each driver itself.

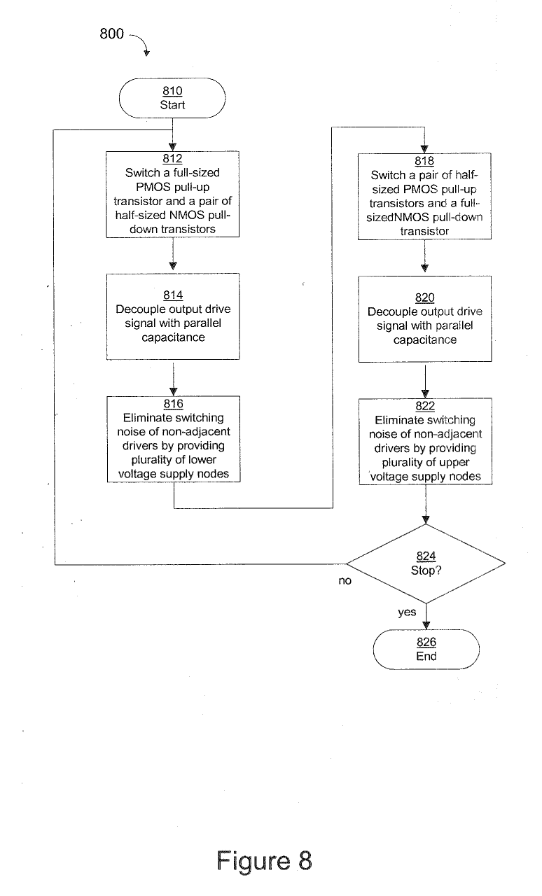

Turning to FIG. 8, a method for driving an output of a semiconductor memory device is indicated generally by the reference numeral 800. The method includes a start block 810 that leads to a function block 812. The function block 812 switches a full-sized PMOS pull-up transistor connected to a pair of half-sized NMOS pull-down transistors to provide an output drive signal therebetween, and leads to a function block 814. The function block 814 decouples the output drive signal with capacitance connected substantially in parallel with the transistors and leads to a function block 816. The function block 816 substantially eliminates the switching noise from non-adjacent drivers by providing a plurality of voltage supply nodes adapted to connect to a lower voltage supply VSSQ, and passes control to a function block 818.

The function block 818, in turn, switches a pair of half-sized PMOS pull-up transistors connected to a full-sized NMOS pull-down transistor to provide an output drive signal therebetween, and leads to a function block 820. The function block 820 decouples the output drive signal with capacitance connected substantially in parallel with these transistors, and leads to a function block 822. The function block 822 substantially eliminates the switching noise from non-adjacent drivers by providing a plurality of voltage supply nodes adapted to connect to an upper voltage supply VDDQ, and passes control to a decision block 824.

The decision block 824 determines whether the output is complete. If incomplete, it passes control back to the function block 812. If complete, it passes control to the end block 826.

Referring back to FIG. 5, the corresponding method 800 of FIG. 8 for driving an output of a semiconductor memory device is further described. The method may include switching a transistor P33 of a first type connected to a transistor N33 of a second type to provide an output drive signal therebetween, decoupling the output drive signal with at least one capacitor C33 connected substantially in parallel with the first and second transistors, and reducing the switching noise by providing a plurality of first voltage supply nodes adapted to connect to a first voltage supply VDDQ and a plurality of second voltage supply nodes adapted to connect to a second voltage supply VSSQ, and providing at a first plurality of the transistors N33 of the first or second type another transistor N32 of the first or second type, respectively, commonly connected at the connection with the transistor P33 of the second or first type, respectively, but separately connected to different first or second voltage supply nodes of VSSQ, respectively. Thus, noise coupling is eliminated for non-adjacent drivers, and substantially reduced for adjacent drivers due to halving the current flow from the instant voltage supply node to the adjacent drivers.

Various alternate embodiments are possible. For example, an output driver may include two transistors having their drains commonly connected and each of two sources of the two transistors connected to a separate power supply node, and a decoupling capacitor connected to each source. Another driver may also include a third transistor connected to the drains of the two transistors and connected to a third power supply node.

A different driver may also include separate power supply nodes connected to the sources of the two transistors adapted to be connected to a common power supply. A further driver may include separate power supply nodes connected to the sources of the two transistors and adapted to be connected to a common power supply, and the third power supply node is adapted to be connected to a second power supply. Some output drivers may use PMOS transistors for the first two transistors and NMOS for the third. The common power supply may provide a more positive voltage than the second power supply. In other output drivers, the first two transistors may be NMOS transistors.

In addition, an output driver circuit may have a plurality of connected drivers, each driver having a transistor of a first type connected to a transistor of a second type to provide an output drive signal therebetween, and at least one decoupling capacitor, the output driver circuit including a plurality of first voltage supply nodes adapted to connect to a first voltage supply and a plurality of second voltage supply nodes adapted to connect to a second voltage supply, where at each odd driver, the transistor of the first type is made up of two transistors commonly connected at the connection with the transistor of the second type, but separately connected to different first voltage supply nodes. A further driver may have at each even driver the transistor of the second type made up of two transistors commonly connected at the connection with the transistor of the first type but separately connected to different second voltage supply nodes.

Drivers may also have the transistors of the first type as PMOS and the transistors of the second type as NMOS. Each driver may include two decoupling capacitors, one downstream and one upstream, for example. The two transistors at each odd driver may about one half of the size of the transistor of the first type. In addition, each of the two transistors at each even driver may be about one half of the size of the transistor of the second type.

Yet another output driver circuit may include one of the two transistors that make up the transistor of the first type connected to the first voltage supply node downstream of the odd driver, and the other of the two transistors connected to the first voltage supply node upstream of the odd driver. Here, one of the two transistors that make up the transistor of the second type may be connected to the second voltage supply node connected downstream of the even driver and the other of the two transistors may be connected to the second voltage supply node connected upstream of the even driver.

The aggregate current drive of the two transistors of the second type is about the same as the current drive of the one transistor of the first type. The first voltage supply node may be connected downstream of each odd driver with a second voltage supply node connected downstream of each even driver.

Although illustrative embodiments have been described herein with reference to the accompanying drawings, it is to be understood that the present disclosure is not limited to those precise embodiments, and that various other changes and modifications may be effected therein by those of ordinary skill in the pertinent art without departing from the scope or spirit of the present disclosure. All such changes and modifications are intended to be included within the scope of the present disclosure as set forth in the appended claims.

What is claimed is:

1. An output driver comprising:
two transistors having their drains commonly connected and each of two sources of the two transistors connected to a separate power supply node; and
a decoupling capacitor connected to each source.

2. The driver of claim 1, further including a third transistor connected to the drains of the two transistors and connected to a third power supply node.

3. The driver of claim 1 wherein the separate power supply nodes connected to the sources of the two transistors are adapted to be connected to a common power supply.

4. The driver of claim 2, wherein the separate power supply nodes connected to the sources of the two transistors are adapted to be connected to a common power supply and the third power supply node is adapted to be connected to a second power supply.

5. The driver of claim 1, wherein the two transistors are PMOS transistors.

6. The driver of claim 2 wherein the third transistor is an NMOS transistor.

7. The driver of claim 4, wherein the common power supply provides a more positive voltage than the second power supply.

8. The driver of claim 1, wherein the two transistors are NMOS transistors.

9. An output driver circuit having a plurality of connected drivers, each driver having a transistor of a first type connected to a transistor of a second type to provide an output drive signal therebetween, and at least one decoupling capacitor, the output driver circuit comprising:
a plurality of first voltage supply nodes adapted to connect to a first voltage supply and a plurality of second voltage supply nodes adapted to connect to a second voltage supply, and
at each odd driver, the transistor of the first type is made up of two transistors commonly connected at the connection with the transistor of the second type, but separately connected to different first voltage supply nodes.

10. The circuit of claim 9, wherein at each even driver, the transistor of the second type is made up of two transistors commonly connected at the connection with the transistor of the first type, but separately connected to different second voltage supply nodes.

11. The circuit of claim 9, wherein the transistors of the first type are PMOS and the transistors of the second type are NMOS.

12. The circuit of claim 9, wherein each driver includes two decoupling capacitors, one downstream and one upstream.

13. The circuit of claim 9, wherein each of the two transistors at each odd driver is about one half of the size of the transistor of the first type.

14. The circuit of claim 10, wherein each of the two transistors at each even driver is about one half of the size of the transistor of the second type.

15. The circuit of claim 9, wherein one of the two transistors that make up the transistor of the first type is connected to the first voltage supply node connected downstream of the odd driver and the other of the two transistors is connected to the first voltage supply node connected upstream of the odd driver.

16. The circuit of claim 10, wherein one of the two transistors that make up the transistor of the second type is connected to the second voltage supply node connected downstream of the even driver and the other of the two transistors is connected to the second voltage supply node connected upstream of the even driver.

17. The circuit of claim 9, wherein the aggregate current drive of the two transistors is about the same as the current drive of the transistor of the first type.

18. The circuit of claim 9, wherein a first voltage supply node is connected downstream of each odd driver and a second voltage supply node is connected downstream of each even driver.

19. A method of driving an output of a semiconductor memory device, the method comprising:
switching a transistor of a first type connected to a pair of transistors of a second type to provide an output drive signal therebetween;
decoupling the output drive signal with at least one capacitor connected substantially in parallel with the first and pair of second transistors, and
reducing the switching noise by providing a plurality of voltage supply nodes, each adapted to connect to one of the pair of transistors of the second type.

20. A method as defined in claim 19, further comprising:
switching a pair of transistors of the first type connected to a transistor of the second type to provide an output drive signal therebetween;
decoupling the output drive signal with at least one capacitor connected substantially in parallel with the pair of first and second transistors, and
reducing the switching noise by providing a plurality of voltage supply nodes, each adapted to connect to one of the pair of transistors of the first type.
